(19) United States
(12) Patent Application Publication
(10) Pub. No.: US 2008/0169198 A1
(43) Pub. Date: Jul. 17, 2008

(54) Method of manufacturing thin film magnetic head

(75) Inventors: Hideaki Daimatsu, Kawasaki-shi (JP); Takashi Ito, Kawasaki-shi (JP)

Correspondence Address: GREER, BURNS & CRAIN, 300 S WACKER DR, 25TH FLOOR, CHICAGO, IL, 60606, US

(73) Assignee: Fujitsu Limited, Kawasaki-shi (JP)

(21) Appl. No.: 11/986,082

(22) Filed: Nov. 20, 2007

(30) Foreign Application Priority Data
Jan. 16, 2007 (JP) 2007-006480

(51) Int. Cl. C25D 5/00; C23C 14/32

(52) U.S. Cl. 205/80; 204/192.34

(57) ABSTRACT

A method of manufacturing a thin film magnetic head can suppress dulling of a magnetic pole tip portion of a write magnetic pole during ion milling carried out when forming the write magnetic pole, and can also suppress fluctuation and nonuniformity in the write core width of the write magnetic pole. The method includes a laminating process of successively laminating a lower magnetic pole layer, a gap layer on the lower magnetic pole layer, and an upper magnetic pole layer on the gap layer to produce a laminated film and an ion milling process of irradiating the laminated film produced by successively laminating the lower magnetic pole layer, the gap layer, and the upper magnetic pole layer from above with an ion beam to trim the laminated film to a narrow width and thereby form the lower magnetic pole layer, the gap layer, and the upper magnetic pole layer into a write magnetic pole. During the ion milling process, trimming is carried out using an ion beam with a first divergence angle and then trimming is carried out using an ion beam with a second divergence angle that differs to the first divergence angle.

### BACKGROUND OF THE INVENTION

1. Field of the Invention

The present invention relates to a method of manufacturing a thin film magnetic head including an ion milling process that irradiates a laminated film, which has been produced by successively laminating a lower magnetic pole layer, a gap layer, and an upper magnetic pole layer in that order, with an ion beam to trim the laminated film into a narrow width and thereby form the lower magnetic pole layer, the gap layer, and the upper magnetic pole layer into a write magnetic pole.

2. Related Art

A conventional method of manufacturing a thin film magnetic head is disclosed in Patent Document 1. FIGS. 4 and 5 are schematic diagrams showing a thin film magnetic head manufactured by this conventional method of manufacturing a thin film magnetic head. Note that in FIGS. 4 and 5, the cross section shown in the nearside of the diagrams is the float surface when the thin film magnetic head is completed.

In the conventional method of manufacturing a thin film magnetic head, first as shown in FIG. 4, an insulating layer 2 made of alumina, for example, is formed on a substrate 1 made of Al₂O₃·TiC, for example. Next, a lower shield layer 3 that forms part of a reproduction head and is made of permalloy (Ni₈₀Fe₂₀), for example, is formed on the insulating layer 2.

Next, a shield gap layer 5 made of alumina, for example, is formed on the lower shield layer 3. After this, an MR film 6 for constructing an MR element that is the principal part of the reproduction head portion is formed in a desired shape on the shield gap layer 5. Next, a lead layer (not shown) as a lead electrode layer for electrically connecting the MR film 6 is formed on both sides of the MR film 6. In addition, a shield gap film 7 made of alumina, for example, is formed on the lead layer, the shield gap layer 5, and the MR film 6 so that the MR film 6 is buried inside the shield gap layers 5, 7.

Next, an upper shield layer 8 is formed on the shield gap film 7. The material that forms the upper shield layer 8 is the same as the lower shield layer 3. After this, an insulating film 9 made of alumina, for example, is formed on the upper shield layer 8.

Next, a lower magnetic layer 10a made of a magnetic material with a high saturation flux density, such as permalloy (in more detail, Ni₄₅Fe₅₅, Ni₈₀Fe₂₀, or the like) is formed with a thickness of around 0.8 to 1.5 microns on the insulating film 9.

After this, a lower magnetic layer 10b made of a magnetic material with a high saturation flux density, such as iron nitride, is formed on the lower magnetic layer 10a. When the lower magnetic layer 10b is formed, the thickness thereof is set thicker than the thickness of a thin film coil 12 that will be formed in a later process. Note that as the material forming the lower magnetic layer 10b, aside from iron nitride, it is possible to use an amorphous alloy with a similar high saturation flux density to iron nitride, such as iron cobalt (FeCo) alloy, zirconium cobalt iron oxide (FeCoZrO) alloy, or zirconium iron nitride (FeZrN) alloy.

A lower magnetic pole layer 10 is composed of the lower magnetic layer 10a and the lower magnetic layer 10b.

Next, the part of the lower magnetic layer 10b where the thin film coil 12 will be formed is removed by etching, such as by ion milling. This can be realized by carrying out etching in a state where a mask that exposes only the formation position of the thin film coil 12 has been formed on the lower magnetic layer 10b.

After this, an antiferromagnetic layer 11 made, for example, of alumina is formed at the exposed parts of the lower magnetic layer 10a and the lower magnetic layer 10b.

Next, the thin film coil 12 for an inductive recording head made of copper (Cu), for example, is formed on the insulating film 11 by carrying out electroplating, for example.

In addition, the thin film coil 12 is buried by an insulating layer 14 made, for example, of alumina.

After this, a gap layer 15 made of a nonmagnetic material, for example alumina, is smoothly formed with a thickness of around 0.1 to 0.15 μm by sputtering, for example, on the lower magnetic pole layer 10 composed of the lower magnetic layer 10a and the lower magnetic layer 10b. Note that as the material that forms the gap layer 15, aside from the alumina mentioned above, it is possible to use a similar nonmagnetic metal material to alumina, such as nickel copper (NiCu) alloy, silicon oxide, ruthenium, or the like.

After this, a base magnetic layer 18 is formed with a thickness of around 0.3 to 1.0 μm by sputtering, for example, on the gap layer 15 across the position where the pole tip of the write magnetic pole will be formed and the periphery thereof. As the material that forms the base magnetic layer 18, as one example it is possible to use a material (such as iron nitride) with a higher saturation flux density than the saturation flux density of a magnetic material (for example, nickel cobalt alloy) that constructs an upper magnetic layer 19 that will be formed in a later process.

An insulating film pattern 17 is formed around the base magnetic layer 18 on the gap layer 15.

Next, the upper magnetic layer 19 composed of a magnetic material with a high saturation flux density, such as iron nickel cobalt alloy (CoNiFe, where Co: 45% by weight, Ni: 30% by weight, Fe: 25% by weight) is selectively formed by frame plating (electroplating) with a thickness of around 1.5 to 2.0 μm on the base magnetic layer 18 and the insulating film pattern 17.

When the upper magnetic layer 19 is formed, a magnetic pole tip portion 19a is formed with a fixed width (around 0.1 to 0.2 μm) so as to extend from the float surface toward the inside, and a yoke portion 19d whose width gradually increases toward the inside is formed at a position further inside. As one example, this can be realized by photolithography where electroplating is carried out in a state where a resist film, in which an exposed portion has been formed in the shape of the upper magnetic layer 19, has been formed on the base magnetic layer 18 and the insulating film pattern 17.

Next, by carrying out ion milling with the upper magnetic layer 19 as a mask, the base magnetic layer 18 and the periphery thereof are selectively etched. By carrying out this etching process, as shown in FIG. 5, the base magnetic layer 18, the gap layer 15, and the surface side of the lower magnetic pole layer 10 are trimmed so as to substantially assume the shape of the upper magnetic layer 19, thereby forming a write magnetic pole (magnetic pole part) 100.

In addition, an overcoat layer (not shown) made of an insulating material such as alumina is formed so as to cover all parts exposed to the surface.

Finally, the float surface of the recording head and reproduction head are formed by machining and lapping to complete the thin film magnetic head.

However, in the conventional method of manufacturing a thin film magnetic head described above, when the write magnetic pole 100 is formed by carrying out ion milling with the upper magnetic layer 19 as a mask to trim the gap layer 15 and the lower magnetic pole layer 10 so as to substantially assume the shape of the upper magnetic layer 19, the upper magnetic layer 19 itself is simultaneously trimmed and becomes narrower. In other words, the upper magnetic layer 19 is formed wider than the width of the write magnetic pole 100 after the trimming by ion milling (that is, wider than the width of the write magnetic pole 100 of a final thin film magnetic head product) and is reduced to the product width by the trimming.

FIGS. 6 and 7 are schematic diagrams showing the shapes of the lower magnetic pole layer 10, the gap layer 15, and the upper magnetic pole layer (the upper magnetic layer 19 and the base magnetic layer 18) before and after trimming is carried out. FIG. 6 is a cross-sectional view of the write magnetic pole 100 when looking from the float surface side and FIG. 7 is a view of the write magnetic pole 100 when looking from above in the laminating direction. In FIGS. 6 and 7, the shapes before trimming are shown by solid lines and the shapes after trimming are shown by broken lines.

Although an intermediate portion 19b and a back end portion 19c are formed with a stepped shape between the magnetic pole tip portion 19a which has a fixed width and the yoke portion 19d whose width gradually increases toward the inside in the upper magnetic layer 19 shown in FIGS. 4 and 5 (Patent Document 1), the magnetic pole tip portion 19a and the yoke portion 19d are continuously formed in the example shown in FIG. 7 (as the shape of an upper magnetic pole, the shape shown in FIG. 7 is more typical).

### Patent Document 1

Japanese Laid-Open Patent Publication No. 2002-123905 (Paragraphs 0041 to 0073 and FIGS. 12 and 13)

### SUMMARY OF THE INVENTION

During the ion milling carried out when forming the write magnetic pole 100, if ion milling is carried out with an ion beam with a divergence angle of around 15°, as shown in FIG. 7 (a diagram where the write magnetic pole 100 is viewed from above in the laminating direction), the peripheries 19e (broken lines) of the boundary between the magnetic pole tip portion 19a and the yoke portion 19d of the write magnetic pole 100 become rounded and the magnetic pole tip portion 19a (broken lines) of the upper magnetic pole layer is dulled so as to become gradually narrower toward the front end (i.e., toward the float surface).

In particular, when the magnetic pole tip portion 19a of the write magnetic pole 100 is cut during the formation of the float surface in a state where the magnetic pole tip portion 19a has become narrower like the magnetic pole shown in FIG. 7, the write core width Wa, Wb of the magnetic pole tip portion 19a tends to fluctuate according to the cutting position (for example, the position a or the position b in FIG. 7). As a result, there are problems such as the write characteristics becoming unstable and greater fluctuation between products.

If the divergence angle of the ion beam used during ion milling is reduced to around 3°, for example, the dulling of the magnetic pole tip portion can be reduced and the magnetic pole tip portion can be formed with a substantially equal width from the boundary with the yoke portion to the float surface.

However, the present inventor has found a problem with a write magnetic pole formed using an ion beam with a small divergence angle in that as shown in FIG. 8 (a cross-sectional view where the write magnetic pole 100 is viewed from the float surface side), concaves and convexes are formed in the upper magnetic layer 19 and the surface of the lower magnetic pole layer 10, which means increased fluctuation in the write core width of the write magnetic pole 100 and leads to greater fluctuation in the write characteristics.

There is also the problem that since grain aggregates of crystals are left in particular near the bottom surface of the part of the lower magnetic pole layer 10 that has been ion milled, there is an increase in the width 10d of the lower magnetic pole layer 10, which prevents the width of the write core of the write magnetic pole 100 from becoming uniform.

The present invention was conceived to solve the problem described above and it is an object of the present invention to provide a method of manufacturing a thin film magnetic head that can suppress dulling of the magnetic pole tip portion of the write magnetic pole during ion milling carried out when forming the write magnetic pole and can also suppress fluctuation and non-uniformity in the write core width of the write magnetic pole.

The present inventor ascertained that when the divergence angle of the ion beam was set low, although there is little deterioration in the shape of the write magnetic pole, at the same time the shapes of the crystal grain boundaries (i.e., the shapes of the crystal grain aggregates) of the lower magnetic pole layer and the upper magnetic pole layer formed by plating or sputtering are also reproduced, with such crystal grain boundaries causing the concave and convex shape described above.

By carrying out extensive research into a method that can smooth out such concaves and convexes due to the shape of the crystal grain boundaries to smoothly form the surface of the magnetic pole and can also form the magnetic pole tip portion sharply without dulling, the present inventor completed the present invention.

To solve the stated problems, a method of manufacturing a thin film magnetic head according to the present invention includes: a laminating process of successively laminating a lower magnetic pole layer, a gap layer on the lower magnetic pole layer, and an upper magnetic pole layer on the gap layer to produce a laminated film; and an ion milling process of irradiating the laminated film produced by successively laminating the lower magnetic pole layer, the gap layer, and the upper magnetic pole layer from above with an ion beam to trim the laminated film to a narrow width and thereby form the lower magnetic pole layer, the gap layer, and the upper magnetic pole layer into a write magnetic pole, wherein during the ion milling process, trimming is carried out using an ion beam with a first divergence angle and then trimming is carried out using an ion beam with a second divergence angle that differs to the first divergence angle.

In addition, the first divergence angle may be below 10° and the second divergence angle may be at least 10°. Alternatively, the first divergence angle may be at least 10° and the second divergence angle may be below 10°.

In the ion milling process, the ratio of a processing time of trimming using the ion beam with the first divergence angle to a processing time of trimming using the ion beam with the second divergence angle may be in a range of 1:9 to 9:1, inclusive.

By doing so, concaves and convexes due to the shape of the crystal grain boundaries can be smoothed out by the ion beam with the wider divergence angle and the magnetic pole tip portion can be sharply formed without dulling by the ion beam with the narrower divergence angle.

During the laminating process, after the gap layer is formed, the upper magnetic pole layer may be formed wider than the write magnetic pole on the surface of the gap layer, and during the ion milling process, the ion beam may trim the upper magnetic pole layer to the width of the write magnetic pole and may also trim the gap layer and at least a surface side of the lower magnetic pole layer exposed from the upper magnetic pole layer to form the write magnetic pole.

During the laminating process, a conductive layer may be formed on the gap layer and the upper magnetic pole layer may be formed by electroplating with the conductive layer as an electroplating seed layer.

With the method of manufacturing a thin film magnetic head according to the present invention, it is possible to suppress dulling of a magnetic pole tip portion of a write magnetic pole during ion milling carried out when forming the write magnetic pole and to also suppress fluctuation and nonuniformity in the write core width of the write magnetic pole.

### BRIEF DESCRIPTION OF THE DRAWINGS

FIG. 1 is a schematic diagram showing a thin film magnetic head manufactured using a method of manufacturing a thin film magnetic head according to the present invention;

FIG. 2 is a schematic diagram showing a thin film magnetic head manufactured using a method of manufacturing a thin film magnetic head according to the present invention;

FIG. 3 is a schematic diagram showing the shape of a write magnetic pole (i.e., upper magnetic pole) when viewed from above in the laminating direction before and after trimming is carried out during an ion milling process in the method of manufacturing a thin film magnetic head according to the present invention (where the shape before trimming is shown by solid lines and the shape after trimming is shown by broken lines);

FIG. 4 is a schematic diagram showing a thin film magnetic head manufactured according to the method of manufacturing a thin film magnetic head disclosed in Patent Document 1;

FIG. 5 is a schematic diagram showing a thin film magnetic head manufactured according to the method of manufacturing a thin film magnetic head disclosed in Patent Document 1;

FIG. 6 is a schematic diagram showing the shape of a write magnetic pole when viewed from the float surface side before and after trimming is carried out during an ion milling process (where the shape before trimming is shown by solid lines and the shape after trimming is shown by broken lines);

FIG. 7 is a schematic diagram showing the shape of a write magnetic pole (i.e., upper magnetic pole) when viewed from above in the laminating direction before and after trimming is carried out during a conventional ion milling process which uses only an ion beam with a divergence angle of around 15°) (where the shape before trimming is shown by solid lines and the shape after trimming is shown by broken lines); and

FIG. 8 is a schematic diagram showing the shape of a write magnetic head when viewed from the float surface side for the case where an ion milling process has been carried out using only an ion beam with a divergence angle of around 3°.

### DESCRIPTION OF THE PREFERRED EMBODIMENT

A preferred embodiment of a method of manufacturing a thin film magnetic head according to the present invention will now be described.

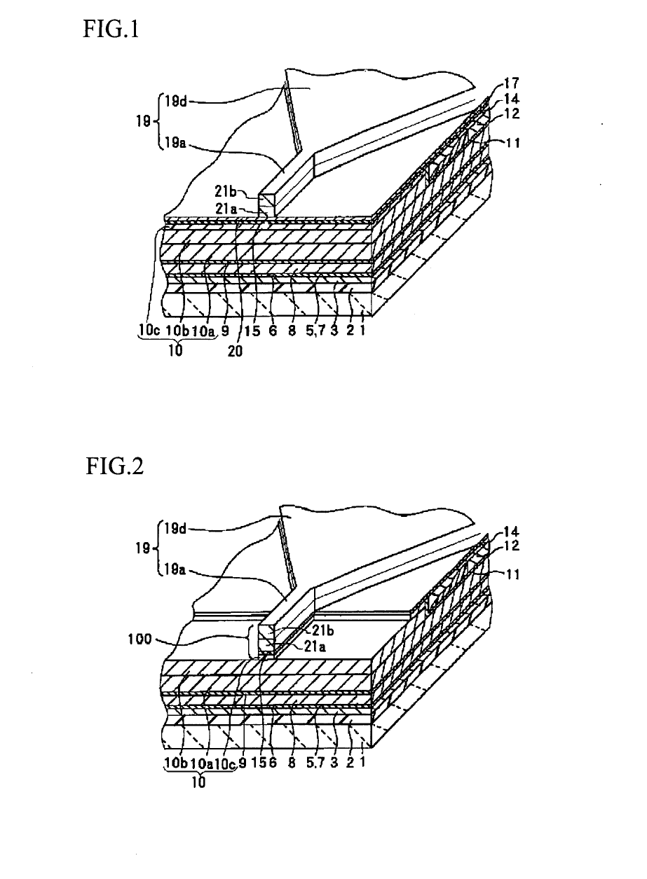

FIGS. 1 and 2 are schematic diagrams showing a thin film magnetic head manufactured by a method of manufacturing a thin film magnetic head according to the present embodiment. Note that in FIGS. 1 and 2, the cross section shown in the near side of the drawings is the float surface when the thin film magnetic head is completed.

In the method of manufacturing a thin film magnetic head according to the present embodiment, since the process that forms the reproduction head is the same as that described above in the “Related Art” section, detailed description thereof is omitted. Therefore, the method of forming the layers above the lower magnetic pole layer 10 that compose the recording head will be described below with reference to FIGS. 1 and 2.

Note that in FIGS. 1 and 2, members that are the same as the thin film magnetic heads shown in FIGS. 4 and 5 have been assigned the same reference numerals and description thereof is omitted.

A lower magnetic layer 10a made of a magnetic material with a high saturation flux density, such as permalloy, is formed on the insulating film 9 shown in FIG. 1.

Next, a lower magnetic layer 10b made in the same way of permalloy is formed on the lower magnetic layer 10a. When the lower magnetic layer 10b is formed, the thickness thereof is set thicker than the thickness of a thin film coil 12 that will be formed in a later process.

In addition, a lower magnetic layer 10c made of cobalt iron (FeCo) alloy is formed on the lower magnetic layer 10b.

The lower magnetic layer 10a, the lower magnetic layer 10b, and the lower magnetic layer 10c construct a lower magnetic pole layer 10.

Next, a part of the lower magnetic layer 10b and the lower magnetic layer 10c where the thin film coil 12 will be formed is removed by etching, such as ion milling. This is realized by carrying out etching in a state where a mask that exposes only the formation position of the thin film coil 12 has been formed on the lower magnetic layer 10c.

After this, an insulating film 11 made of alumina, for example, is formed at the exposed parts of the lower magnetic layer 10a, the lower magnetic layer 10b, and the lower magnetic layer 10c.

Next, the thin film coil 12 for an inductive recording head made of copper (Cu), for example, is formed by electroplating, for example, on the insulating film 11.

In addition, the thin film coil 12 is buried by an insulating layer 14 made of alumina, for example.

After this, a gap layer 15 made of a nonmagnetic material, such as silicon oxide, is smoothly formed by sputtering, for example, on the lower magnetic pole layer 10 composed of the lower magnetic layer 10a and the lower magnetic layer 10b. Note that as the material forming the gap layer 15, aside from the silicon oxide mentioned above, it is possible to use another nonmagnetic metal material, such as alumina, nickel copper (NiCu) alloy, or ruthenium.

An insulating layer (not shown in the drawings) for forming a zero throat is formed on the insulating layer 14 that buries the thin film coil 12.

After the gap layer 15 has been formed, a conductive layer, which is used as a seed layer 20 for electroplating that forms an upper magnetic layer 19, is formed on the gap layer 15 and the insulating layer that forms the zero throat. The upper magnetic layer 19 is formed by electroplating with the seed layer 20 as a power supply layer (note that in FIG. 2, the seed layer 20 is treated as being integrated with the upper magnetic layer 19 and is therefore omitted from the drawing). The seed layer 20 can be composed of cobalt iron (FeCo) oxide, for example.

Next, by carrying out frame plating (electroplating) on the seed layer 20, a first magnetic layer 21 a made of a magnetic material with a high saturation flux density, such as nickel iron cobalt (NiFeCo) alloy is selectively formed on the seed layer 20. In addition, a second magnetic layer 21b made of permalloy is formed on the first magnetic layer 21a.

The upper magnetic layer 19 is constructed of the first and second magnetic layers 21a, 21b.

Note that although in the upper magnetic layer 19 shown in FIGS. 4 and 5 (Patent Document 1), the intermediate portion 19b and the back end portion 19c are formed with a stepped shape between the magnetic pole tip portion 19a whose width is fixed and the yoke portion 19d whose width gradually increases toward the inside, in the present embodiment shown in FIGS. 1 and 2, the magnetic pole tip portion 19a and the yoke portion 19d are continuously formed.

However, the present invention is not limited to the construction of the present embodiment and includes a method of manufacturing a thin film magnetic head where an intermediate portion and a back end portion are formed in the upper magnetic layer as shown in FIGS. 4 and 5.

Next, by carrying out ion milling with the upper magnetic layer 19 as a mask, the base magnetic layer 18 and the periphery thereof are selectively etched. As shown in FIG. 2, this etching process trims the seed layer 20, the gap layer 15 and the surface of the lower magnetic pole layer 10 (the lower magnetic layer 10c) to substantially assume the shape of the upper magnetic layer 19, thereby forming the write magnetic pole (magnetic pole part) 100.

In addition, an overcoat layer (not shown) made of an insulating material such as alumina is formed so as to cover all parts exposed to the surface.

Finally, the float surface of the recording head and reproduction head are formed by machining and lapping to complete the thin film magnetic head.

In the method of manufacturing a thin film magnetic head according to the present embodiment, the ion milling process that is carried out when forming the write magnetic pole after the upper magnetic layer 19 (the upper magnetic pole layer) has been formed has the following characteristic.

In this ion milling process, ion milling is first carried out using an ion beam with a divergence angle (a “first divergence angle”) of below 10° and preferably around 3° and then ion milling is carried out using an ion beam with a divergence angle (a “second divergence angle”) of at least 10° and preferably around 15°.

Note that during the ion milling process, it is possible to use a plurality of ion mill devices whose divergence angles have been set differently and to carry out ion milling using the respective devices in order or to use a single device with a plurality of processing chambers in which the divergence angle of the ion beam is set differently, with ion milling being carried out in the respective processing chambers in order.

The divergence angle of the ion beam in each ion mill device or each processing chamber can be set according to beam conditions (such as the irradiation power of the beam).

Also, as the ion milling processing time for each divergence angle, ion milling is first carried out for five minutes with the divergence angle at 3° and is then carried out for five minutes with the divergence angle at 15°. Note that the processing times are not limited to the times given above and can be adjusted as appropriate in accordance with the intensity of the ion beam and the like.

Note that the present inventor confirmed that the effects of suppressing the dulling of the magnetic pole tip portion of the formed write magnetic pole and of suppressing fluctuation and nonuniformity in the write core width of the write magnetic pole favorably appear when the ratio of the processing time for trimming carried out using an ion beam with a divergence angle of 3° to the processing time for trimming carried out using an ion beam with a divergence angle of 15° is in a range of 1:9 to 9:1, inclusive.

In addition, the present inventor confirmed that substantially the same effects can be achieved even when the order for carrying out the ion milling using an ion beam with a divergence angle of 3° and the ion milling using an ion beam with a divergence angle of 15° is reversed.

During the ion milling process, an ion beam is emitted from a direction that is substantially parallel to the surface of the substrate 1 and the substrate 1 is rotated within a plane that is parallel to the surface of the substrate 1.

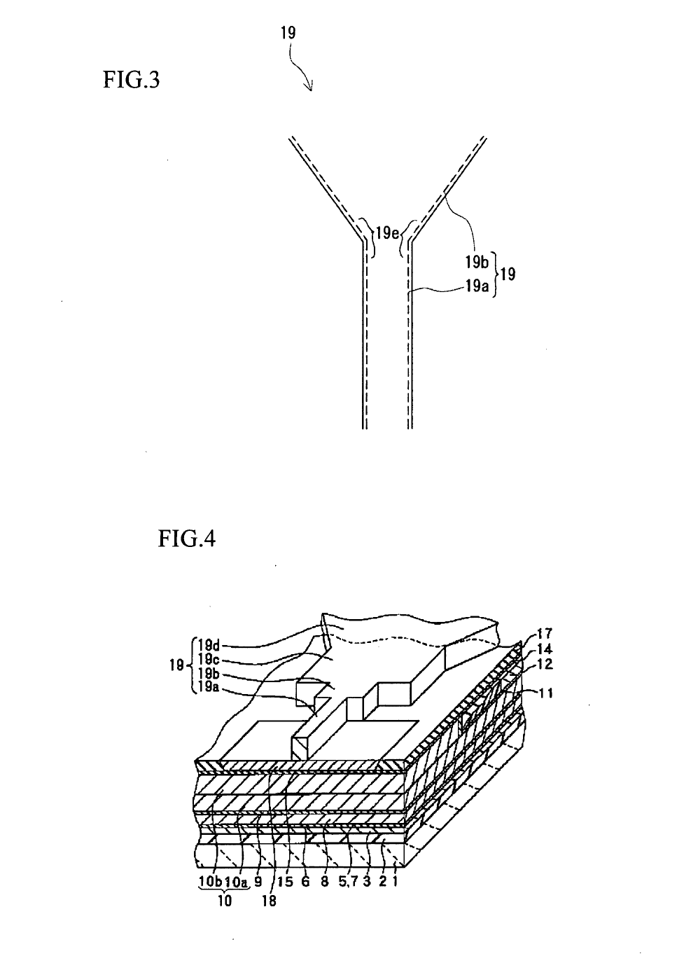

FIG. 3 is a schematic diagram showing the shapes of the lower magnetic pole layer 10, the gap layer 15, and the upper magnetic pole layer (the upper magnetic layer 19) before and after trimming in the method of manufacturing a thin film magnetic head according to the present embodiment when viewed from above in the laminating direction. In FIG. 3, the shapes before trimming are shown by solid lines and the shapes after trimming are shown by broken lines.

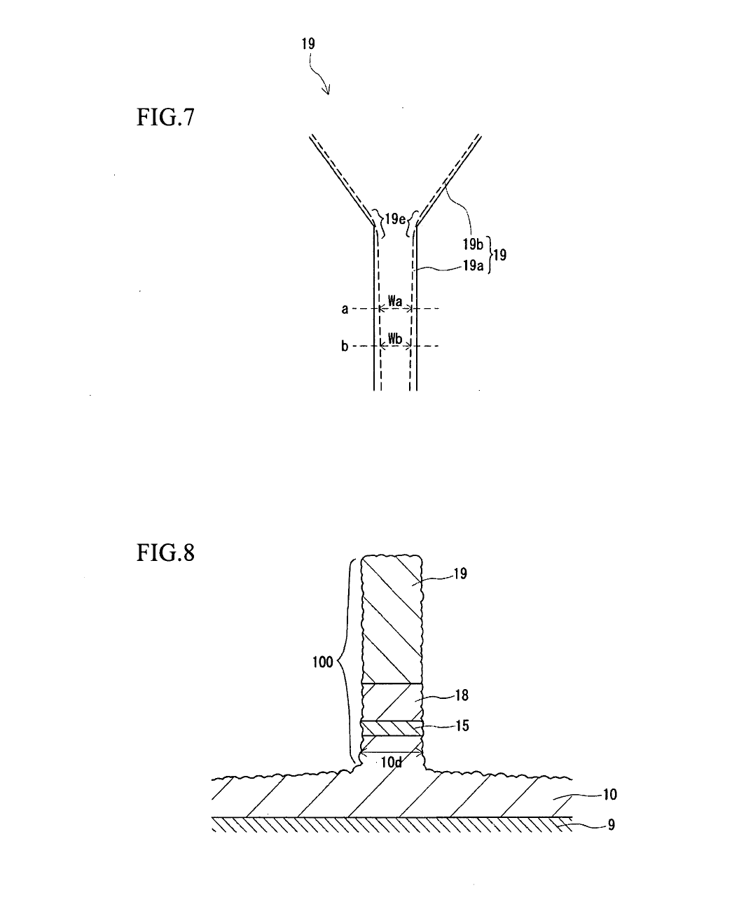

As shown in FIG. 7, the magnetic pole tip portion 19a of the write magnetic pole formed using only an ion beam with a divergence angle of around 15° narrows toward the tip of the magnetic pole (i.e., toward the float surface).

On the other hand, as shown in FIG. 3, the magnetic pole tip portion 19a of the write magnetic pole formed by the method of manufacturing a magnetic head according to the present invention is formed with a substantially uniform width.

In this way, by using the method of manufacturing the magnetic head according to the present embodiment, it is possible to suppress the dulling (i.e., tapering) of the magnetic pole tip portion 19a of the formed write magnetic pole.

Also, by using the method of manufacturing a magnetic head according to the present embodiment, the periphery 19e of the boundary between the magnetic pole tip portion 19a and the yoke portion 19d of the write magnetic pole 100 can also be sharply formed.

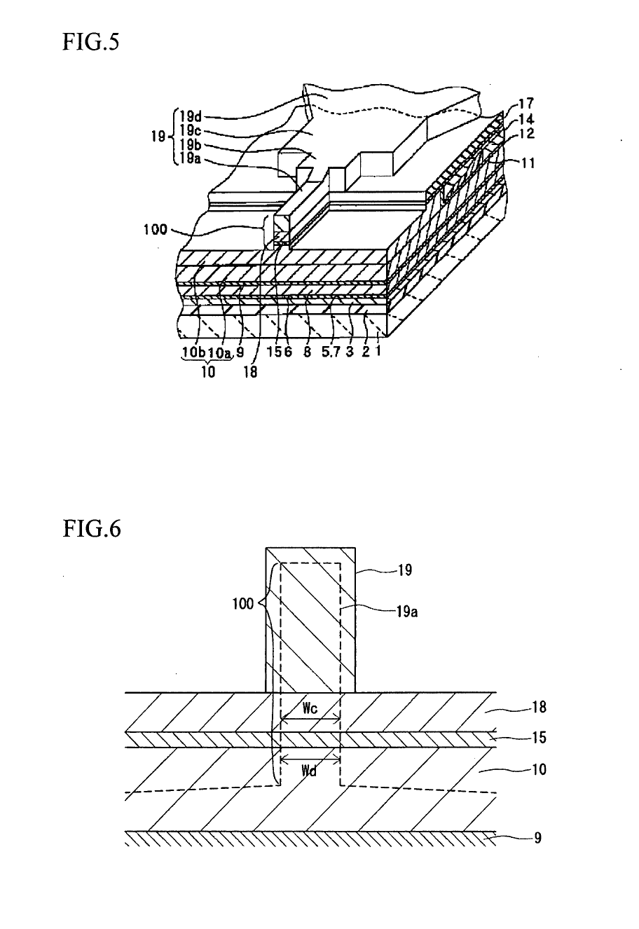

The present inventor measured the fluctuation in the shape of a write magnetic pole formed by the method of manufacturing a magnetic head according to the present embodiment and a write magnetic pole formed using only an ion beam with a divergence angle of 3°. As the measurement method, as shown in FIG. 6, a difference (Wd-Wc) between the width Wc of the upper part of the upper magnetic pole on one side of the gap layer 15 and the width Wd of the lower part of the upper magnetic pole on the other side of the gap layer 15, that is, fluctuation in the core width between upper and lower parts of the upper magnetic pole on both sides of the gap layer 15 was measured for a plurality of magnetic heads manufactured according to both methods of manufacturing.

As a result, for the write magnetic poles formed using only an ion beam with a divergence angle of 3°, the fluctuation (Wd-Wc) in the write core width between upper and lower parts of the write magnetic pole was large at around 10 nm to 50 nm. The average of such value was also high at around 30 nm, and therefore it was understood that the write core width was nonuniform on both sides of the gap layer.

On the other hand, for a write magnetic pole formed using the method of manufacturing a magnetic head according to the present embodiment, the fluctuation (Wd-Wc) in the write core width above and below the gap layer 15 was small at around −5 to 20 nm. The average of such value was also small at around 10 nm, and it was found that the write core width was substantially uniform on both sides of the gap layer.

In this way, with the method of manufacturing a thin film magnetic head according to the present embodiment, compared to the conventional case where only an ion beam of around 15° was used, it is possible to suppress the irradiation time for an ion beam with a large (at least 10°) divergence angle to around half. This means that it is possible to suppress the dulling of the magnetic pole tip portion of the write magnetic pole.

In addition, compared to the case where only an ion beam of around 3° is used, by emitting an ion beam with a divergence angle of around 15° (or at least 10°), it is possible to smoothly spread out the crystal grain aggregates, which means that it is possible to suppress fluctuation and nonuniformity in the width of the write core of the write magnetic pole.

What is claimed is:

1. A method of manufacturing a thin film magnetic head, comprising:
a laminating process of successively laminating a lower magnetic pole layer, a gap layer on the lower magnetic pole layer, and an upper magnetic pole layer on the gap layer to produce a laminated film; and
an ion milling process of irradiating the laminated film produced by successively laminating the lower magnetic pole layer, the gap layer, and the upper magnetic pole layer from above with an ion beam to trim the laminated film to a narrow width and thereby form the lower magnetic pole layer, the gap layer, and the upper magnetic pole layer into a write magnetic pole,
wherein during the ion milling process, trimming is carried out using an ion beam with a first divergence angle and then trimming is carried out using an ion beam with a second divergence angle that differs to the first divergence angle.

2. The method of manufacturing a thin film magnetic head according to claim 1, wherein the first divergence angle is below 10° and the second divergence angle is at least 10°.

3. The method of manufacturing a thin film magnetic head according to claim 1, wherein the first divergence angle is at least 10° and the second divergence angle is below 10°.

4. The method of manufacturing a thin film magnetic head according to claim 1,
wherein in the ion milling process, the ratio of a processing time of trimming using the ion beam with the first divergence angle to a processing time of trimming using the ion beam with the second divergence angle is in a range of 1:9 to 9:1, inclusive.

5. The method of manufacturing a thin film magnetic head according to claim 1,
wherein during the laminating process, after the gap layer is formed, the upper magnetic pole layer is formed wider than the write magnetic pole on the surface of the gap layer, and
during the ion milling process, the ion beam trims the upper magnetic pole layer to the width of the write magnetic pole and also trims the gap layer and at least a surface side of the lower magnetic pole layer exposed from the upper magnetic pole layer to form the write magnetic pole.

6. The method of manufacturing a thin film magnetic head according to claim 1,
wherein during the laminating process, a conductive layer is formed on the gap layer and the upper magnetic pole layer is formed by electroplating with the conductive layer as an electroplating seed layer.
